(19) United States
(12) Patent Application Publication
(10) Pub. No.: US 2020/0098675 A1
(43) Pub. Date: Mar. 26, 2020

(54) CHIP ON FILM, DISPLAY PANEL, DISPLAY DEVICE

(71) Applicants: Interface Technology (ChengDu) Co., Ltd., Chengdu (CN); INTERFACE OPTOELECTRONICS (SHENZHEN) CO., LTD., Shenzhen (CN); GENERAL INTERFACE SOLUTION LIMITED, Zhunan (TW)

(72) Inventors: CHIEN-WEN CHANG, Zhunan (TW); TA-JEN HUANG, Zhunan (TW); YIN-CHENG CHEN, Zhunan (TW)

(21) Appl. No.: 16/239,575

(22) Filed: Jan. 4, 2019

(30) Foreign Application Priority Data
Sep. 25, 2018 (CN) 201811114336.5

(51) Int. Cl. H01L 23/498; H01L 23/00

(52) U.S. Cl. CPC H01L 23/49811; H01L 23/49838; H01L 24/29

(57) ABSTRACT

A chip on film (COF) to automatically allow for a shifting in the positions of conductive pins connecting the chip and a display panel includes pins sequentially arranged along a first direction and spaced apart from each other. Each pin includes a first end and a second end, and each pin defines a virtual extension line extending from its first end to its second end. The virtual extension lines of at least some of the pins obliquely converge on a reference line that is perpendicular to the first direction. A display panel includes pins which are created and installed to match the pins of the COF. A display device and a method for designing, creating, and installing such pins are also provided.

### FIELD

The subject matter herein generally relates to a chip on film, a display panel, and a display device.

### BACKGROUND

Flat panel displays typically include a display panel and a driving circuit. The driving circuit is electrically connected to the display panel to control the display of the display panel. Known methods of achieving electrical connections between the driving circuit and the display panel include COF (chip on film) or COG (chip on glass) etc. In the COF technology, the driving circuit is disposed on the COF configured to connect to the display panel, by bonding between pins of COF and pins of driving for achieving the electrical connections.

Development trends of the display devices are large size, narrower frames and higher resolutions etc. Therefore, the requirements for precision in bonding between COF and display panel are higher and higher. Due to the high density of pins on the COF cause the bonding yield and reliability of the COF to be low quality.

Therefore, there is room for improvement in the art.

### BRIEF DESCRIPTION OF THE DRAWINGS

Implementations of the present disclosure will now be described, by way of example only, with base to the attached figures.

FIG. 1 is a planar view showing a first embodiment of a chip on film (COF).

FIG. 2A is a planar view of the COF shown in FIG. 1 before being bonded with a display panel.

FIG. 2B is a planar view showing a display device using the COF shown in FIG. 1.

FIG. 3 is a planar view showing a second embodiment of a COF.

FIG. 4 is a planar view showing a third embodiment of a COF.

FIG. 5 is a planar view showing a first embodiment of a display panel.

FIG. 6A is a planar view showing COF and display panel of FIG. 5 before being bonded together.

FIG. 6B is a planar view showing a display device using the display panel shown in FIG. 5.

FIG. 7 is a planar view showing a second embodiment of a display panel.

FIG. 8 is a planar view showing a display device using the display panel shown in FIG. 7.

FIG. 9 is a planar view showing a third embodiment of a display panel.

FIG. 10 is a planar view showing a display device using the display panel shown in FIG. 9.

FIG. 11 is a schematic flow chart of a method for making pins.

### DETAILED DESCRIPTION

It will be appreciated that for simplicity and clarity of illustration, where appropriate, base numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, etc. The disclosure is illustrated by way of example and not by way of limitation in the figures of the accompanying drawings in which like bases indicate similar elements. It should be noted that bases to “an” or “one” embodiment in this disclosure are not necessarily to the same embodiment, and such bases can mean “at least one”. The term “circuit” can include an integrated circuit (IC) with a plurality of electric elements, such as capacitors, resistors, amplifiers, etc.

### First Embodiment of Chip on Film (COF)

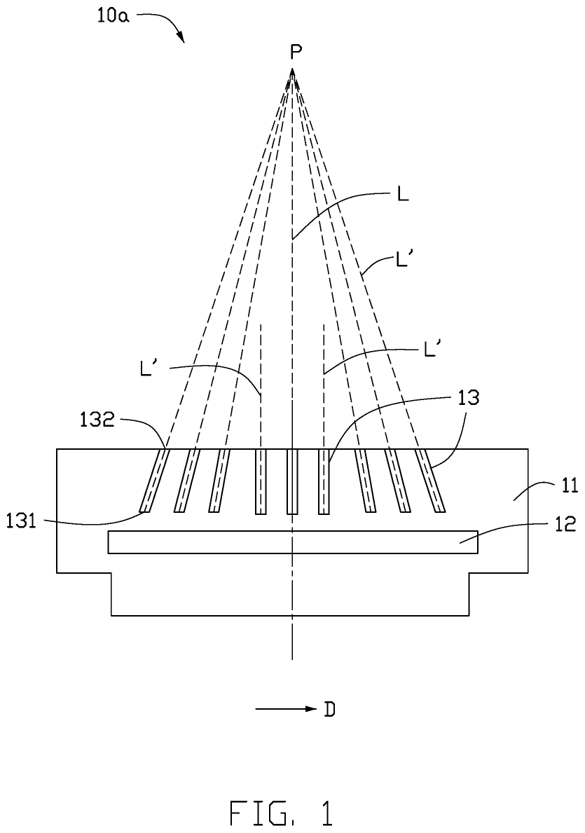

FIG. 1 shows a first embodiment of a chip on film (COF 10a). As shown in FIG. 1, the COF 10a includes a substrate 11, a chip 12 disposed on a surface of the substrate 11, and a plurality of first pins 13 disposed on the surface of the substrate 11 and electrically connected to the chip 12, which sequentially arrange and spaced apart from each other along a first direction D. Each first pin 13 includes a first end 131 and a second end 132 opposite to the first end 131 along an extending direction. In one embodiment, the first end 131 of the first pin 13 is near the chip 12, and the second end 132 of the first pin 13 is away from the chip 12. Each first pin 13 defines a virtual extension line L′ that is a straight line from the first end 131 to the second end 132 and extending away from the second end 132. Part of the virtual extension lines L′ of the first pins 13 intersect a reference line L which is perpendicular to the first direction D.

When the COF 10a receives forces, the substrate 11 may occur expansion or tensile deformation to cause a positional shift of the first pins 13 on the surface of the substrate 11. Generally, the deformation of the substrate 11 may cause the first end 131 shifting toward the reference line L, and the second end 132 shifting away from the reference line L. In one embodiment, part of the virtual extension lines L′ of the first pins 13 intersect the reference line L that can compensate for positional shift of the first pins 13 caused by the deformation of the substrate 11.

In one embodiment, the material of the substrate 11 may be, but is not limited to, polyimide (PI) or polyethylene terephthalate (PET). The chip 12 may be a display-driving chip, or a display-driving chip and a touch control chip packaged together, or a display-driving chip, a touch control chip and a fingerprint identification chip packaged together etc. The shape of the first pin 13 may be a rectangle or a parallelogram, which is not limited herein.

In one embodiment, the reference line L is substantially located at the middle of the substrate 11, and the first pins 13 are symmetrically arranged with respect to the reference line L. The shape of the first pins 13 near the reference line L are a rectangle, and the shape of the first pins 13 away from the reference line L are a parallelogram. The virtual extension lines L′ of the first pins 13 adjacent the reference line L are substantially parallel to the reference line L. The virtual extension lines L′ of the first pins 13 away from the reference line L intersect with the reference line L at a point P. When the virtual extension line L′ of the first pins 13 is farther from the reference line L, the angle between the virtual extension line L′ of the first pin 13 and the reference line L is larger. That is, between the first pins 13 near the edge of the substrate 11 and the reference line L have larger inclination angle. In other embodiments, the reference line L may be located other than at a middle of the substrate 11.

In other embodiments, the first pins 13 of the COF 10a on both sides of the reference line L may be asymmetrically arranged with respect to the reference line L. For example, the number, the distribution density, and the inclination angle of the first pins 13 on the two sides of the reference line L may be different.

In other embodiments, the first pins 13 of the COF 10a may be only disposed on one side of the reference line L.

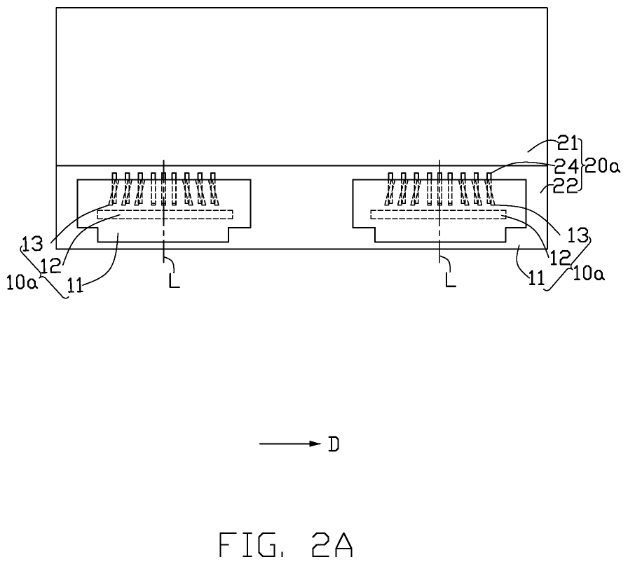

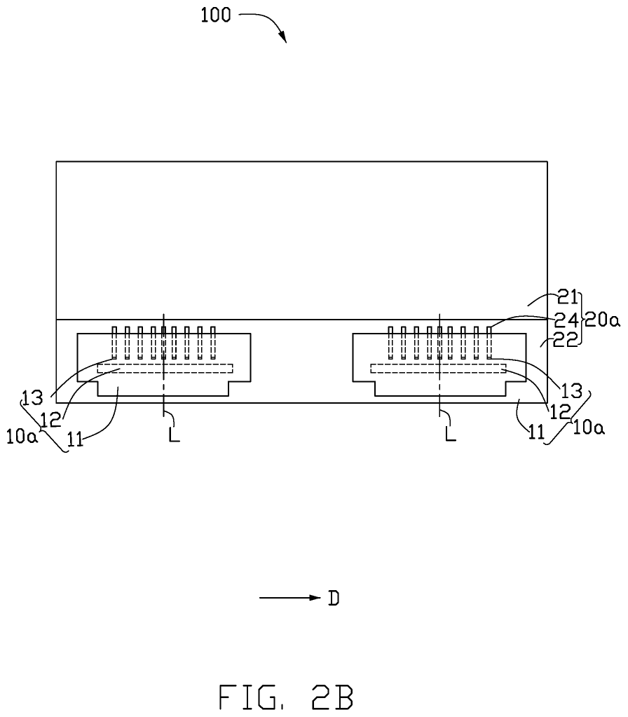

FIG. 2A is a schematic plan view of the COF 10a shown in FIG. 1 before being bonded with a display panel 20a. As shown in FIG. 2A, the display panel 20a defines a display area 21 and a non-display area 22 which is around the display area 21. A plurality of third pins 24 are disposed on the non-display area 22, which sequentially arrange and space apart from each other along the first direction D. Each third pin 24 is a rectangle, which is parallel to the reference line L.

In one embodiment, the number of the COF 10a bonded with the display panel 20a may be one or more. FIG. 2A illustrates schematically two COF 10a bonded with the display panel 20a.

As shown in FIG. 2A, before the COF 10a is bonded with the display panel 20a, the first pins 13 of the COF 10a are in one-to-one corresponding with the third pins 24 of the display panel 20a. The first pin 13 adjacent the reference line L is parallel to and partially overlaps with third pin 24. The first pin 13 away from the reference line L intersects with and partially overlaps the third pin 24.

In one embodiment, during a process of bonding between the COF 10a and the display panel 20a, the substrate 11 may occur expansion or tensile deformation due to material properties of the substrate 11 or parameters setting. Such deformation may cause a position shift of the first pins 13 on the surface of the substrate 11. The expansion or tensile deformation of the substrate 11 adjacent the reference line L is less than the expansion or deformation of the substrate 11 away from the reference line L. The portions of the substrate 11 farthest away from the reference line L suffer the greatest expansion or tensile deformation. Generally, the material properties or other parameters at symmetrical positions of the substrate 11 are the same or similar, and the expansion or tensile deformation of these symmetrical portions are substantially the same.

In one embodiment, during the process of bonding between the COF 10a and the display panel 20a, the first pins 13 adjacent the reference line L are substantially stable and do not shift. As shown in FIG. 2B, when the display device 100 completing the process of binding between the COF 10a and the display panel 20a, the first pins 13 adjacent the reference line L and the third pins 24 on the display panel 20a remain parallel.

In one embodiment, during the process of bonding between the COF 10a and the display panel 20a, the first end 131 of the first pin 13 of the virtual extension line L′ intersecting with the reference line L shifts toward reference line L. The second end 132 of the first pin 13 of the virtual extension line L′ intersecting with the reference line L shifts away from the reference line L. As shown in FIG. 2B, when the display device 100 completing the process of bonding between the COF 10a and the display panel 20a, the first pins 13 away from the reference line L are substantially parallel to the third pins 24 on the display panel 20a.

In one embodiment, during the process of bonding between the COF 10a and the display panel 20a, the substrate 11 may occur expansion or tensile deformation due to material properties of the substrate 11 or parameters setting. Such that cause a position shift of the first pins 13 on the surface of the substrate 11. Part of the virtual extension lines L′ of the first pins 13 intersect the reference line L that can compensate for the positional shift of the first pins 13. Thus, the bonding yield and reliability of the COF 10a and the display panel 20a are improved.

### Second Embodiment of COF

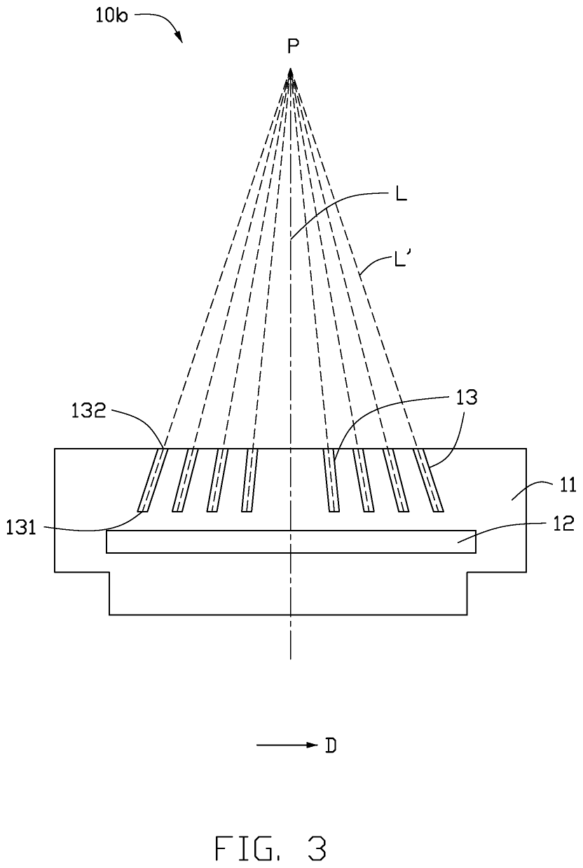

FIG. 3 is a schematic plan view of the second embodiment of a COF (COF 10b). The COF 10b is substantially the same as the COF 10a of the first embodiment. The COF 10b includes a substrate 11, a chip 12 disposed on a surface of the substrate 11. A plurality of first pins 13 is disposed on the surface of the substrate 11 and electrically connected to the chip 12, which sequentially arrange and spaced apart from each other along the first direction D. Each first pin 13 includes a first end 131 and a second end 132 opposite to the first end 131 along an extending direction. In one embodiment, the first end 131 of the first pin 13 is near the chip 12, and the second end 132 of the first pin 13 is away from the chip 12. Each first pin 13 defines a virtual extension line L′ that is a straight line from the first end 131 to the second end 132 and away from the second end 132.

The difference between the COF 10b of this embodiment and the COF 10a of the first embodiment is that the virtual extension lines L′ of all the first pins 13 of COF 10b intersect a reference line L which is perpendicular to the first direction D. In the first embodiment, part of the virtual extension lines L′ of first pins 13 intersect a reference line L which is perpendicular to the first direction D.

### Third Embodiment of COF

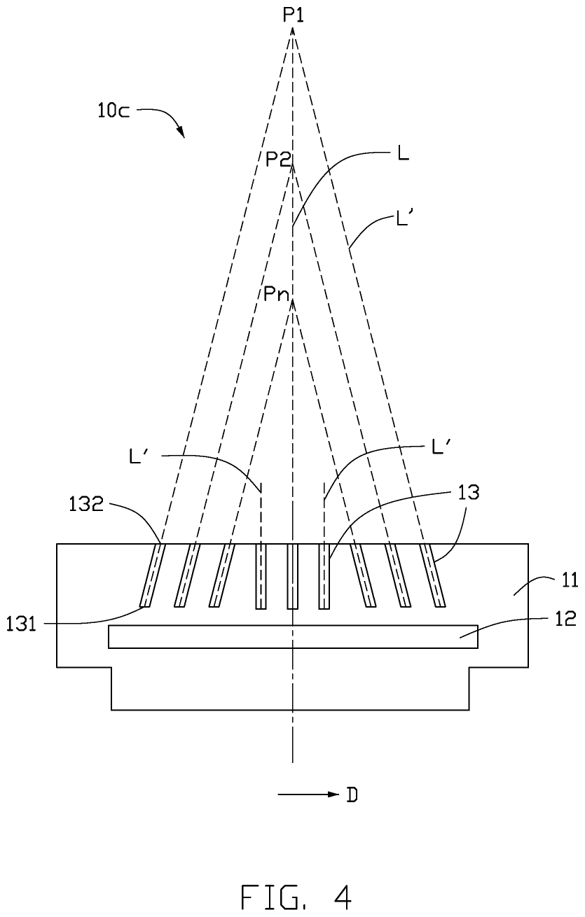

FIG. 4 is a schematic plan view of a third embodiment of a COF (COF 10c). The COF 10c is substantially the same as the COF 10a of the first embodiment. The COF 10c includes a substrate 11, a chip 12 disposed on the surface of the substrate 11. A plurality of first pins 13 disposed on the surface of the substrate 11 and electrically connected to the chip 12, which sequentially arrange and spaced apart from each other along the first direction D. Each first pin 13 includes a first end 131 and a second end 132 opposite to the first end 131 along an extending direction. In this embodiment, the first end 131 of the first pin 13 is near the chip 12, and the second end 132 of the first pin 13 is away from the chip 12. Each first pin 13 defines a virtual extension line L′ that is a straight line from the first end 131 to the second end 132 and extending away from the second end 132. Part of the virtual extension lines L′ of the first pins 13 intersect a reference line L which is perpendicular to the first direction D.

The difference between the COF 10c of this embodiment and the COF 10a of the first embodiment is that the angles between the virtual extension lines L′ intersecting with the reference line L are substantially the same. The extension lines L′ of the first pins 13 intersect the reference line L at different points P1, P2, . . . Pn (n is an integer greater than 1), respectively. In the first embodiment, the distance between the first pin 13 and the reference line L is farther, the angle between the virtual extension line L′ of the first pin 13 and the reference line L is larger. The virtual extension lines L′ of each first pin 13 of COF 10c intersect the reference line L at the same point P.

### First Embodiment of a Display Panel

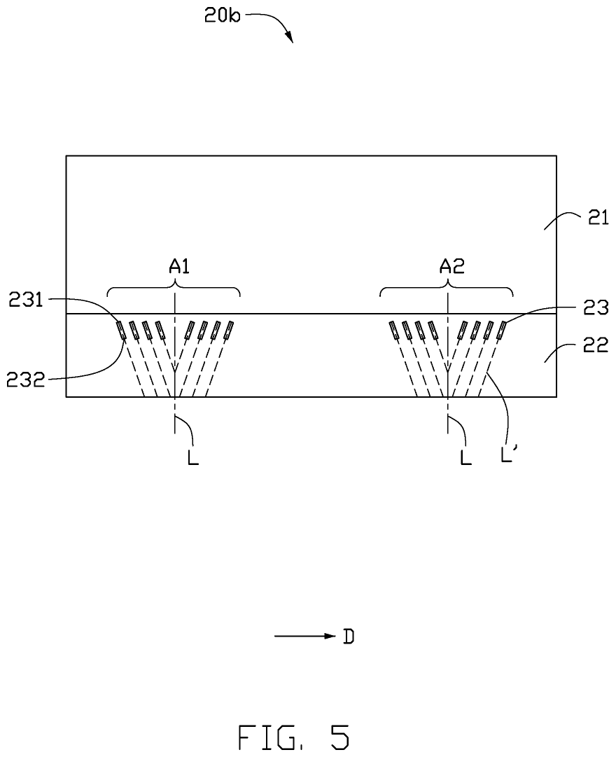

FIG. 5 is a schematic plan view of a first embodiment of a display panel 20b. The display panel 20b defines a display area 21 for displaying a screen and a non-display area 22 around the display area 21. A plurality of second pins 23 are disposed on the non-display area 22, which sequentially arrange and space apart from each other along a first direction D. Each second pin 23 includes a first end 231 and a second end 232 opposite to the first end 231 along an extending direction. In this embodiment, the first end 231 of the second pin 23 is near the display area 21, and the second end 232 of the second pin 23 is away from the display area 21. Each second pin 23 defines a virtual extension line L′ that is a straight line from the first end 231 to the second end 232 and away from the second end 232. Part of the virtual extension lines L′ of the second pins 23 intersect a reference line L which is perpendicular to the first direction D.

In this embodiment, the second pins 23 are divided into pin groups (two pin groups A1 and A2 are schematically shown in the FIG. 5), and each pin group is bonded with a COF. The second pins 23 in each pin group are symmetrically arranged with respect to the reference line L. The virtual extension lines L′ of all the second pins 23 in each pin group intersect the reference line L, and the angle between the virtual extension line L′ of each second pin 23 intersecting with the reference line L and the reference line L is substantially the same. In other embodiments, the second pins 23 of each pin group of the display panel 20b may be only disposed on one side of the reference line L. Alternatively, the second pins on both sides of the reference line L in each pin group may be asymmetrically arranged with respect to the reference line L. For example, the number, the distribution density, and the inclination angle of the first pins 13 on the two sides of the reference line L may be different.

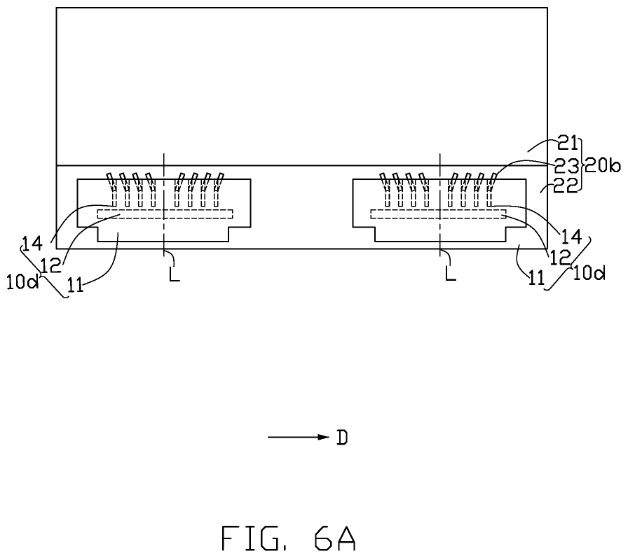

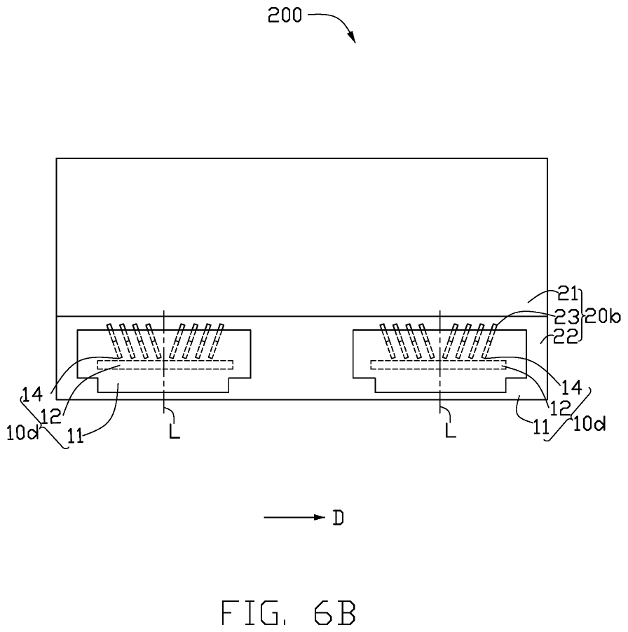

FIG. 6A is a schematic plan view of the COF 10d and the display panel 20b shown in FIG. 5 before being bonded together. As shown in FIG. 6A, a COF 10d includes a plurality of fourth pins 14. The fourth pins 14 are sequentially arranged and spaced apart from each other along the first direction D. Each fourth pin 14 extends in a rectangular strip shape in a direction parallel to the reference line L.

In one embodiment, the number of COF 10d bonded with the display panel 20b may be one or more, and two COF 10d bonded with the display panel 20b are shown in FIG. 6A.

As shown in FIG. 6A, before the COF 10d is bonded with the display panel 20b, the fourth pins 14 of the COF 10d are in one-to-one corresponding with the second pins 23 of the display panel 20b. Each fourth pin 14 intersects with and partially overlaps the second pin 23 on the display panel 20b.

In this embodiment, during a bonding process between the COF 10d and the display panel 20b, due to material properties of the substrate 11 or parameters setting, the substrate 11 may occur expansion or tensile deformation. Such that cause a positional shift of the fourth pins 14 on the surface of the substrate 11. Generally, the material properties or other parameters at the symmetrical positions of the substrate 11 are the same or similar, and the expansion or tensile deformation of the symmetrical positions of the substrate 11 is substantially the same.

In this embodiment, during the process of bonding between the COF 10d and the display panel 20b, the end of each fourth pin 14 near the chip 12 shifts toward a side adjacent the reference line L, and the end of each fourth pin 14 away from the chip 12 shifts away from the reference line L. As shown in FIG. 6B, when the display device 200 completing the process of bonding between the COF 10d and the display panel 20b, the fourth pins 14 of the COF 10d are substantially parallel to the corresponding second pins 23 on the display panel 20b.

In this embodiment, during the process of bonding between the COF 10d and the display panel 20b, due to the material properties of the substrate 11 or parameters setting the substrate 11 may occur expansion or tensile deformation. Such that cause a positional shift of the fourth pins 14 on the COF 10d. The virtual extension line L′ of each second pin 23 on the display panel 20b intersects the reference line L that can compensate for a positional shift of the fourth pins 14 on the COF 10d. Thus, the bonding yield and reliability of the COF 10d and the display panel 20b are improved.

### Second Embodiment of a Display Panel

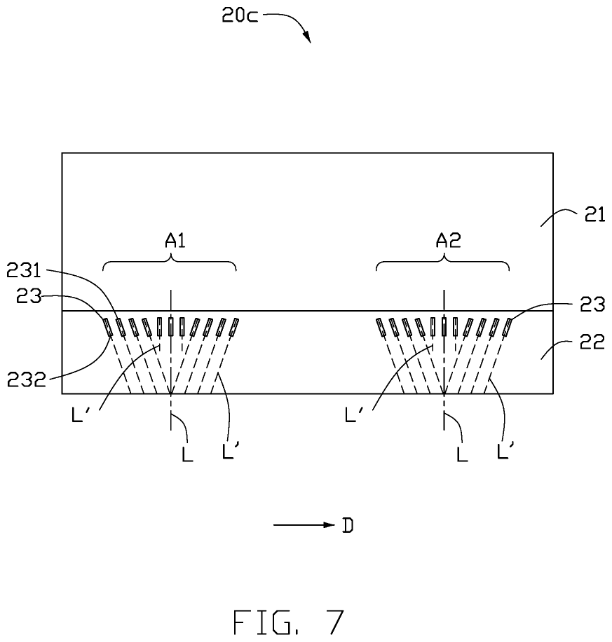

FIG. 7 is a planar view showing a second embodiment of a display panel 20c. As shown in FIG. 7, the display panel 20c is substantially the same as the display panel 20b of the first embodiment. The display panel 20c defines a display area 21 for displaying a screen and a non-display located at a periphery of the display area 21. A plurality of second pins 23 are disposed on the non-display area 22, which sequentially arrange and space apart from each other along the first direction D. Each second pin 23 includes a first end 231 and a second end 232 opposite to the first end 231 along an extending direction. In this embodiment, the first end 231 of the second pin 23 is near the display area 21, and the second end 232 of the second pin 23 is away from the display area 21. Each second pin 23 defines a virtual extension line L′ that is a straight line from the second end 232 to the first end 231 and extending away from the first end 231. Part of the virtual extension lines L′ of the second pins 23 intersect a reference line L which is perpendicular to the first direction D.

The difference between the display panel 20c and the display panel 20b is that, the second pins 23 of 20c adjacent the reference line L are substantially parallel to the reference line L. In the first embodiment, the virtual extension lines L′ of all the second pins 23 are intersecting with the reference line L.

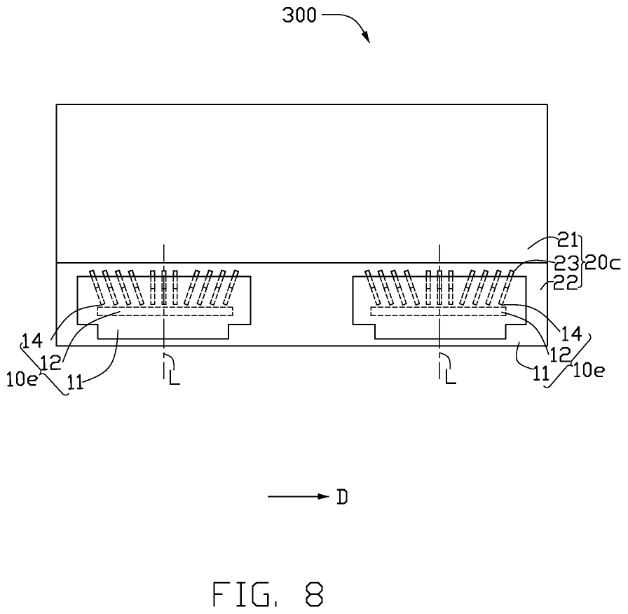

FIG. 8 is a planar view showing a display device 300 using the display panel 20c shown in FIG. 7. In this embodiment, during the process of bonding between the COF 10e to the display panel 20c, the first pins 13 adjacent the reference line L are substantially not shifted. As shown in FIG. 8, in the display device 300 created by bonding the COF 10e to the display panel 20c, each fourth pin 14 of COF 10e adjacent the reference line L and the corresponding second pin 23 of the display panel 20c remain substantially parallel and partially overlap.

In this embodiment, during the process of bonding between the COF 10e to the display panel 20c, the further a portion of the substrate 11 is from the reference line L, the greater is the expansion or tensile deformation of the portion of the substrate 11. One end of the fourth pin 14 of the COF 10e near the chip 12 shifts toward the side adjacent the reference line L, and the other end of the fourth pin 14 of the COF 10e away from the chip 12 shifts away from the reference line L. After the COF 10e is bonded with the display panel 20c, as shown in FIG. 8, the fourth pins 14 away from the reference line L are substantially parallel to and overlapping with the corresponding second pins 23 on the display panel 20c

In this embodiment, during a process of bonding between the COF 10e and the display panel 20c, due to material properties of the substrate 11 or parameters setting, the substrate 11 may occur expansion or tensile deformation. Such that cause a position shift of the fourth pins 14 of the COF 10e. Part of the virtual extension lines L′ of second pins 23 on the display panel 20c intersect the reference line L that can compensate for the position shift of the fourth pins 14. Thus, the bonding yield and reliability of the COF 10e and the display panel 20c are improved.

### Third Embodiment of a Display Panel

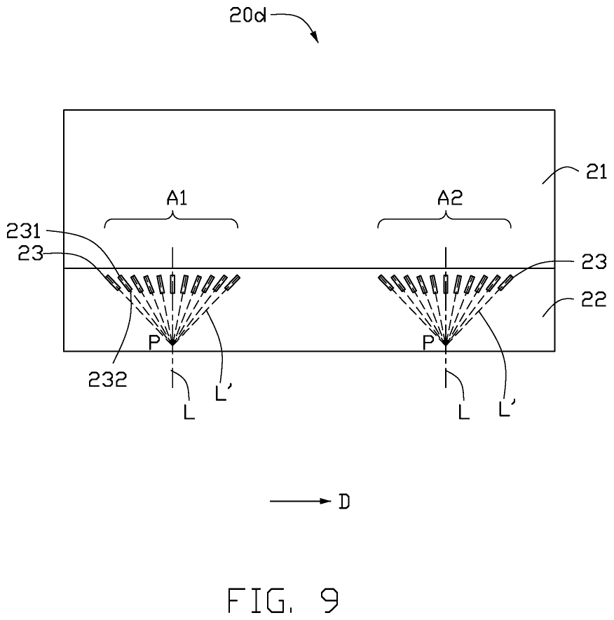

FIG. 9 is a planar view showing a third embodiment of a display panel 20d. The display panel 20d is substantially the same as the display panel 20b of the first embodiment. The display panel 20d defines a display area 21 for displaying a screen and a non-display 22 located at a periphery of the display area 21. A plurality of second pins 23. The second pins 23 are disposed on the non-display area 22, which sequentially arrange and space apart from each other along a first direction D. Each second pin 23 includes a first end 231 and a second end 232 opposite to the first end 231 along an extending direction. In this embodiment, the first end 231 of the second pin 23 is near the display area 21, and the second end 232 of the second pin 23 is away from the display area 21. Each second pin 23 defines a virtual extension line L′ that is a straight line from the first end 231 to the second end 232 and extending away from the second end 232. Part of the virtual extension lines L′ of the second pins 23 intersect a reference line L which is perpendicular to the first direction D.

The difference between the display panel 20d and the display panel 20b is that when the virtual extension line L′ of the second pins 23 of the display panel 20d is farther from the reference line L, the angle between the virtual extension line L′ of the second pin 23 and the reference line L is larger. The virtual extension lines L′ of each second pin 23 intersects the reference line L at a same point P. In the first embodiment of 20b, the angles between the virtual extension line L′ intersecting with the reference line L are substantially the same. The virtual extension lines L′ of the second pins 23 intersect the reference line L at different points.

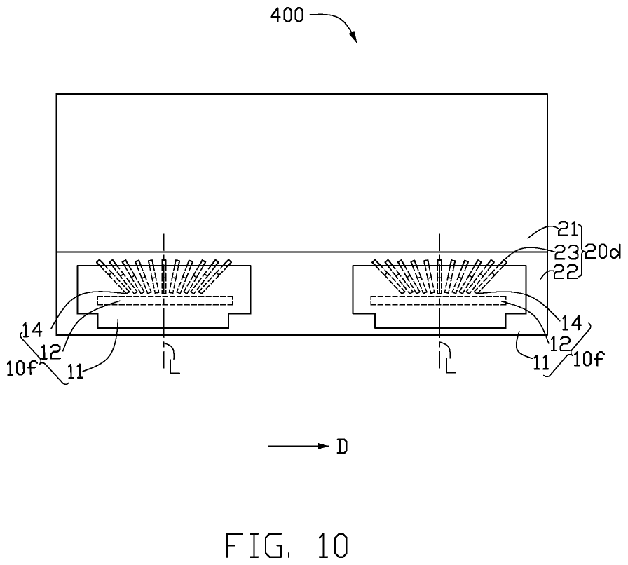

FIG. 10 is a planar view showing a display device 400 using the display panel 20d shown in FIG. 9. In this embodiment, during the process of bonding between the COF 10f and the display panel 20d, the substrate 11 adjacent the reference line L has a small expansion or tensile deformation. The further a portion of the substrate 11 is from the reference line L, the greater is the expansion or tensile deformation of the portion of the substrate 11. The ends of all the fourth pins 14 adjacent the chip 12 shift toward the side adjacent the reference line L, and the ends of all the fourth pins 14 away from the chip 12 shift away from the reference line L. The shifting of the fourth pins 14 adjacent the reference line L is less than the shifting of the fourth pins 14 away from the reference line L. After the COF 10f is bonded with the display panel 20d, as shown in FIG. 10, all the fourth pins 14 on the COF 10f are substantially parallel to and overlap with the corresponding second pins 23 on the display panel 20d.

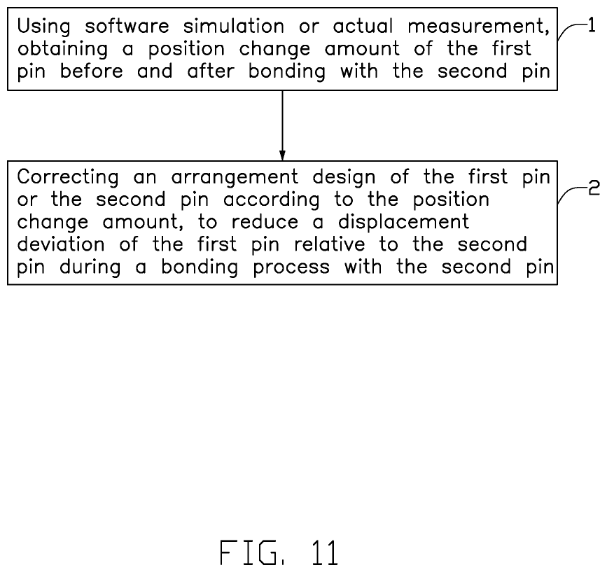

FIG. 11 shows a method for creating and locating pins, wherein the pin includes a first pin on a first to-be-bonded component and a second pin on a second to-be-bonded component for bonding with the first pin. The method includes the following steps:

Step S1: by using software simulation or actual measurement, obtaining a positional change of the first pin between positions of before and after bonding with the second pin;

Step S2: correcting an arrangement of the first pin or the second pin according to the positional change, to reduce a displacement deviation of the first pin relative to the second pin during a bonding process with the second pin.

In one embodiment, the first to-be-applied component is a COF, and the second to-be-applied component is a display panel.

In one embodiment, in step S1, using software simulation or actual measurement, parameters such as pressure and temperature during the bonding process between the COF and the display panel are analyzed, and the position change of the pins between positions of the COF before and after bonding with the pins of the display panel is obtained. The positional change may be a distance of shift or an angle of shift of the pins of the COF after bonding to the pins of the display panel.

In one embodiment, in step S2, after the position change is obtained, it is fed back as it were into the installation of the pins of the COF as a compensation. For example, when the COF is bonded with the display panel, the pins of the COF will shift by a certain distance or angle in a certain direction, and then in the installation of the pins of the COF, the pins of the COF may be shifted by the same distance or angle in an opposite direction.

In another embodiment, in step S2, after the position change is obtained, it is treated as feedback into the design of the pins of the display panel to compensate. For example, when the COF is bonded with the display panel, the pins of the COF are shifted by a certain distance or angle in a certain direction, and then in the design of the pins of the display panel, the pins of the display panel may be shifted by the same distance or angle in an opposite direction.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A chip on film, comprising:
a substrate;
a chip on a surface of the substrate; and
a plurality of pins on the surface of the substrate, and electrically connected to the chip;
wherein the plurality of pins sequentially arrange and space apart from each other along a first direction, and each of the plurality of pins comprises a first end and a second end opposite to the first end;
wherein each of the plurality of pins defines a virtual extension line extending from the each pin, and one part of the virtual extension lines intersect a reference line that is perpendicular to the first direction.

2. The chip on film of claim 1, wherein an distance between each of the pins and the reference line is farther, an angle between the virtual extension line of each of pins and the reference line is larger.

3. The chip on film of claim 1, wherein each of the virtual extension lines adjacent the reference line is parallel to the reference line.

4. The chip on film of claim 2, wherein each of the virtual extension lines adjacent the reference line is parallel to the reference line.

5. The chip on film of claim 1, wherein an angle between the one part of the virtual extension lines intersecting with the reference line and the reference line is the same.

6. A display panel, comprising:
a display area; and
a non-display area located at a periphery of the display area, comprising a plurality of pins sequentially arranged along a first direction and spaced apart from each other, each of the plurality of pins comprising a first end and a second end opposite to the first end;
wherein each of the plurality of pins defines a virtual extension line extending from the first end to the second end, and part of the virtual extension lines of the pins non-perpendicularly intersect a reference line that is perpendicular to the first direction.

7. The display panel of claim 6, wherein an angle is defined between each of the virtual extension lines and the reference line, when the virtual extension line is farther from the reference line, the angle is larger.

8. The display panel of claim 6, wherein each of the virtual extension lines adjacent the reference line is parallel to the reference line.

9. The display panel of claim 6, wherein an angle between the one part of the virtual extension lines intersecting with the reference line and the reference line is the same.

10. A display device, comprising:
a display panel, and
a chip on film bonded with the display panel, the display panel comprising a display area; and a non-display area located at a periphery of the display area, comprising a plurality of pins sequentially arranged along a first direction and spaced apart from each other, each of the plurality of pins comprising a first end and a second end opposite to the first end; wherein each of the plurality of pins defines a virtual extension line extending from the first end to the second end, and part of the virtual extension lines of the pins non-perpendicularly intersect a reference line that is perpendicular to the first direction.

11. The display device of claim 10, wherein an angle is defined between each of the virtual extension lines and the reference line, when the virtual extension line is farther from the reference line, the angle is larger.

12. The display device of claim 10, wherein each of the virtual extension lines adjacent the reference line is parallel to the reference line.

13. The display device of claim 10, wherein an angle between the one part of the virtual extension lines intersecting with the reference line and the reference line is the same.
